(19) United States
(12) Patent Application Publication
(10) Pub. No.: US 2024/0282602 A1
(43) Pub. Date: Aug. 22, 2024

(54) ELECTRICAL ARRANGEMENT WITH A POSITIONING AID, AND PRODUCTION METHOD

(71) Applicant: Robert Bosch GmbH, Stuttgart (DE)

(72) Inventors: Gerhard Braun, Rottenburg (DE); Wolfram Kienle, Magstadt (DE)

(21) Appl. No.: 18/571,803

(22) PCT Filed: May 30, 2022
(86) PCT No.: PCT/EP2022/064639

§ 371 Date: Dec. 19, 2023

(30) Foreign Application Priority Data
Jun. 25, 2021 (DE) 10 2021 206 587.2

(51) Int. Cl. H01L 21/67; H01L 21/44; H01L 21/48

(52) U.S. Cl. CPC H01L 21/67144; H01L 21/44; H01L 21/4825; H01L 21/67259

(57) ABSTRACT

A production method and an electrical arrangement (1) are proposed. The electrical arrangement (1) comprises a power substrate (2) with an electrical conductive track (3), an insulating structure (4) and a sheet metal conducting structure (5) having a first contact region (6), a connection region (11) and a first connecting region (9) between the first contact region (6) and the connection region (11), wherein the contact region (6) is connected to the electrical conductor track (3) electrically, in particular with a material bond, in a recess (12) in the insulating structure (4), merges into the connecting region (9) at an angle along an edge (7) running in an X direction and has a lug (8) for positioning the conducting structure (5), which lug extends in a Y direction over an imaginary extension of the edge (7).

### BACKGROUND

The present invention relates to an electrical arrangement with a positioning aid, as well as a method for producing said arrangement. In particular, the present invention relates to an electrical arrangement comprising a raised insulating structure on a power substrate.

Modern power substrates are sometimes based on a ceramic structure with metallic upper and lower surfaces. The circuit breakers (IGBT, MOSFET, etc.) are then assembled (equipped) and wired. By virtue of the substrate, decompensation is only possible in two-dimensional space. Bonds, also referred to as “ribbons” and “wires” or the like, are provided as external contacts. Punched parts contacted by ultrasonics or laser welding are also used. In packaged power substrates of this type, i.e., those with raised insulating structures, it is also common to position a connecting element at the same time and to allow it to project beyond the packaging edge. The term “packaging edge” refers to an insulating structure surrounding the edges of the power substrate. The protruding connection element is then used for external electrical contacting.

Contacting the packaging edge above a surface of the power substrate causes a reduction of a creepage current distance between the upper and the lower sides over the surface of the insulating structure.

In addition, there is a need for electrical arrangements that have as little inductance in the commutation circuit as possible and that provide an electrotechnical component that is suitable for production and that is insensitive to tolerance and has a low inductance design. At the same time, the robustness of the factory assembly steps should be enabled and ensured.

### SUMMARY

According to the invention, an electrical arrangement is proposed, which is particularly suitable for use in power circuits. Such power circuits are required, e.g., in the field of electric mobility, where an AC voltage or multi-phase voltage required to operate a traction machine has to be generated from an onboard DC voltage source. The electrical arrangement comprises a power substrate with an electrical conductor track that has an insulating structure. For example, the insulating structure can also be injected onto the power substrate in the form of a foam. Doing so in particular creates an electrical insulation between an upper and lower surface of the power substrate with a predefined creepage distance (creepage current distance). For this purpose, the insulating structure can release individual contact regions on the power substrate, which are electrically connected to the electrical conductor track. In other words, the insulating structure can surround the contact surfaces and thereby provide edges arranged at predefined positions around the contact surfaces (e.g., according to window or frame type). A sheet metal conducting structure is further provided, which has a three-dimensional design. The conducting structure comprises a first contact region, which is galvanically connected to the contact surface on the power substrate. The conducting structure further comprises a connection region for external electrical contacting, and a first connecting region connecting the first contact region and the connection region. In particular, the connecting region can ensure a conveyance of currents between the contact region and the connection region when the contact region and the connection region do not extend along the same plane. The contact region can be electrically connected to the contact surface or the electrical conductive track of the power substrate, in particular with a material bond. For this purpose, the insulating structure comprises a recess (window/frame), within which the contact region of the conducting structure rests flat on the power substrate. The contact region is bent at an angle along an edge, or merges into the connecting region in another way. Such a deformation of the conducting structure sheet is sometimes associated with increased tolerances and does not provide a clearly defined possibility of an interlocking fit enclosing the edge in the region of the edge, since the edge typically has a similar radius/bend. Sometimes the angle of the connecting region to the plane of the first contact region cannot always be designed precisely due to the production process. A lug for positioning the conducting structure is therefore provided, which extends over an intended extension of the edge in a direction perpendicular to the direction of the edge. In other words, whereas the edge transitions from the first contact region to the connecting region, a lug remains adjacent to the edge in the plane of the first contact region, which features a particularly cut or punched distal edge, which has lower tolerances than the spatial location of the connecting region. In particular, the connecting region can be guided out of the window in the insulating structure without contacting the insulating structure, while the lug positions the first contact region and thus the conducting structure in the electrical arrangement through the window in the insulating structure via insertion, in particular by fitting, preferably by clamping, into the window in the insulating structure with an opposite edge of the first contact region. Very precise positioning of the conducting structure on the power substrate or with regard to the insulating structure can as a result be ensured, whereas the creepage distance across the insulating structure is particularly low, since the lug is located directly on the power substrate and does not contact “higher” layers of the insulating structure.

The lug can be situated in a common plane with the contact region by not deforming the lug opposite the first contact region after cutting out the sheet metal conducting structure. The lug basically forms a flat tongue at the first contact region of the conducting structure, which protrudes laterally at the edge towards the connecting region or protrudes beyond the edge towards the connecting region. It can in this way can be ensured that the connecting region is situated at a distance from the insulating structure, said distance being predefined by the lug, and the connecting region does not reduce the creepage current distance over the insulating structure.

A particularly inexpensive option for producing the sheet metal conducting structure can be to laser-cut or punch the outer shape of the planar conducting structure, whereupon a bending procedure results in the edge extending in the X direction between the first contact region and the first connecting region. Optionally, an edge can also be provided between the connection region used for external contacting and the first connecting region in order to connect the conducting structure to an external electrical periphery in a direction parallel to the surface of the power substrate. Given the process, a radius on the convex side of the conducting structure in the region of the edge can be created, which is not suitable for positioning arranged near the power substrate by the insulating structure. The lug, which is omitted during the bending process, helps in this respect. The cutting edge of the lug is therefore provided as a positioning aid, beyond or adjacent to the edge between the connecting region and the first contact region.

Preferably, the electrical arrangement comprises further contact regions and optionally also further connecting regions. A second contact region and a second connecting region can thus be provided between the second contact region and the connection region (as previously explained hereinabove). The second contact region can also merge into the second connecting region at an angle along an edge running in an X direction. In particular, the edge between the second contact region and the second connecting region is designed to be flush with the edge between the first contact region and the first connecting region. The second contact region can be designed correspondingly or identically, or be a mirror image of the first contact region. The second contact region is therefore situated in the same direction from the point of view of the connection region, but parallel to the first contact region. In principle, it is also possible to contact the contact regions with the connection region via one and the same connecting region. In any case, the lugs of the two contact regions can cause a predefined, linear contact with respective regions of the insulating structure and thus ensure a particularly secure positioning of the conducting structure. The first and second contact regions can be arranged in a common recess, common window, or common frame of the insulating structure on the power substrate. However, an insulating structure can preferably be provided between both contact regions, which structure can also be used as a positioning aid in the X direction. In other words, the insulating structure forms a connecting portion between the first contact region and the second contact region, which prevents sliding towards the first and second edges. This connecting portion can also have a thickness that increases in the direction of the surface of the power substrate, so that easy positioning of the conducting structure is possible, as tolerances become smaller as the conducting structure approaches the insulating structure.

The lug can preferably be sized in conjunction with the remaining contact region such that a distal end of the lug exactly fits into a recess of the insulating structure with an opposite edge of the contact region. Insofar as a second contact region with a second lug is still present, the above can apply to this leg in a corresponding manner. In particular, given the presence of at least two contact regions with a certain extension in the X direction, an advantageous positioning of the conducting structure in the X direction as well as in the Y direction can be ensured, so a rotation of the conducting structure relative to the power substrate about a Z axis can also be prevented.

An indentation can be provided between the lug and the edge provided between the connecting region and the first contact region, or rather between the second connecting region and the second contact region. For example, the indentation can have a width (i.e. an extension in the X direction) of 0.2 mm, preferably 0.5 mm, particularly preferably 1 mm, and most preferably 2 mm. It can this way be prevented that, after a bending operation following a cut-out of the sheet, a deformation of the lug with respect to the respective contact region is not inadvertently caused. Advantageous positioning of the conducting structure in the window of the insulating structure is therefore always ensured near the substrate.

In other words, and without limitation with respect to the appended claims, the present invention is based on the idea of directly enabling the connection between the module on the substrate-based circuit breaker. This is achieved via an opening/recess in the packaging housing (the insulating structure) of the module. This opening can be designed so it is able to be placed directly on the housing shape of the packaging (insulation) without additional filigree geometries which are difficult to produce. Waste is as a result reduced in the production of the electrical arrangements (modules). Furthermore, the downstream process of releasing the surface of the power substrate in the prior art (sometimes remaining insulation components in the prior art are subsequently laser-burned) can be omitted. By virtue of the flat design of the contact region according to the invention comprising the positioning lugs, the requirements for clearance and creepage distances can be better met.

This inventive design enables simple and secure contacting of the contact regions after insertion/attachment to the power substrate or the contact surface/electrical conductor track for the purpose of welding.

Proposed according to a second aspect of the present invention is a method for producing the electrical arrangement, as described in detail hereinabove. The method comprises applying an insulating structure to the power substrate. The insulating structure is ideally and preferably provided for extending a creepage current distance between an upper side and lower side of the power substrate. Said structure comprises a recess, within which a conducting structure is intended to be electrically contacted. In a further step, the conducting structure is cut from a metal sheet and bent. The lug for positioning in the insulating structure is also created thereby. The contact region is then inserted into a recess in the insulating structure and, as a last step, connected to the electrical conductor track of the power substrate with a material bond. Misalignment of the conducting structure with respect to the power substrate is prevented by an exact fit of the recess with respect to the structure of the contact region together with the lug. Ramp-shaped steep walls in the insulating structure can assist with the insertion of the contact region and reduce the requirements for precise positioning by means of the handling apparatus when equipping the power substrate.

The joining process of the contact region or conducting structure with respect to the power substrate requires proper positioning of the joining partners. The complete surface support for the subsequent joining process must also be enabled as a result. This is done by matching the shape and design of the connecting plate (conducting structure) with the power substrate (circuit breaker). The specification of the punching direction prevents snagging during joining. In other words, the punch, which has the shape of the conducting structure, can be placed on the sheet from the direction in which the power substrate will later be located. A sharp edge or burr that forms on the matrix side of the sheet is thus located at the rear in the joining direction and does not run the risk of getting caught with the insulating structure. The interlocking geometry of the aforementioned joining partners ensures the installation position without the need for additional tooling expenditure.

### BRIEF DESCRIPTION OF THE DRAWINGS

Exemplary embodiments of the invention are described in detail hereinafter with reference to the accompanying drawings. Shown are:

FIG. 1 a schematic side view of an electrical arrangement according to a first exemplary embodiment of the present invention;

FIG. 2 a perspective view of an exemplary embodiment according to the present invention;

FIG. 3 an overhead view of the rear side of an electrical arrangement according to the present invention;

FIG. 4 a sectioned side view through an exemplary embodiment of an electrical arrangement according to the present invention for illustrating a creepage distance; and

FIG. 5 a flowchart illustrating the steps of an exemplary embodiment of a method according to the invention for producing an electrical arrangement.

### DETAILED DESCRIPTION

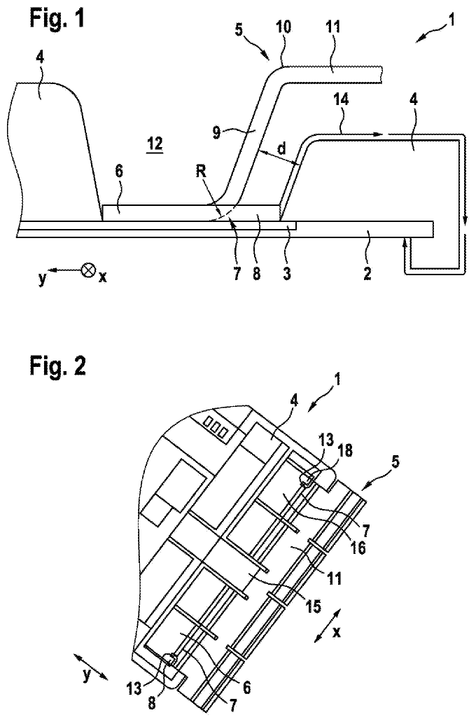

FIG. 1 shows a side view of an exemplary embodiment of an electrical arrangement 1 according to the invention, in which a power substrate 2 comprising an electrical conductor track 3 supports an insulating structure 4 and a conducting structure 5. A contact region 6 of the conducting structure 5 is connected to the electrical conductor track 3 with a material bond. In order to be able to create an electrical contact above the insulating structure 4, an area of an edge that lies in the X direction transitions with a radius R to a first connecting region 9. By way of an edge 10 running parallel to edge 7, the connecting region 9 transitions to a connection region 11. Two edges of the insulating body 4 opposite one another with respect to a Y direction limit a recess 12 in the insulating structure 4. As an extension of the first contact region 6, a lug 8 projects beyond the edge in the X direction in the Y direction and thus provides for a precise positioning and (temporary) determination of the conducting structure 5 in the recess 12 as well as on the electrical conductor track 3. Moreover, the lug 8 ensures a distance b between the connecting region 9 and the insulating structure 4, which prevents accidental contacting of the insulating structure 4 by the connecting region 9 and thus maintains the length of the leakage current section 14.

FIG. 2 shows a perspective representation of an electrical arrangement 1 in which a conducting structure 5 is locked in the X direction by a connecting portion 15. An indentation 13 is provided between the lug 8 and the edge 7, which prevents the lug 8 from being deformed opposite the contact region 6. The second contact region 16 is arranged and designed to be a mirror image of the first contact region 6. The lugs 8, 18 prevent a clearance in the contact regions 6, 16 in the recesses of the insulating structure 4. Further contact regions without lugs and indentations join the common connection region 11 via further connecting regions, via which an external electrical contacting of the electrical arrangement 1 takes place.

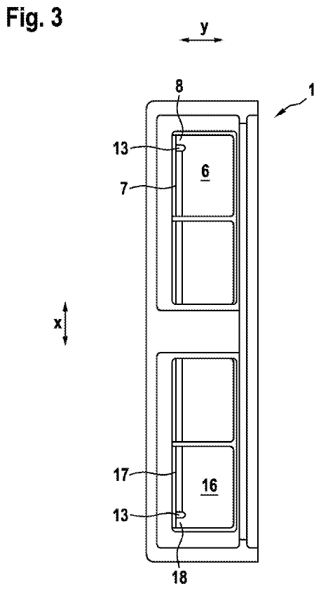

FIG. 3 shows a top view of a lower side of an electrical arrangement 1 according to the present invention. In this view, the layers of the lugs 8, 18 and the indentations 13 arranged between them and the respective edge 7, 17 are clear to see.

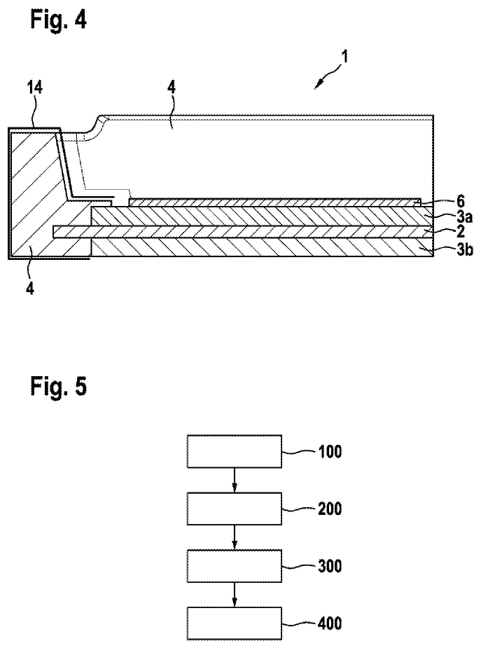

In FIG. 4, a sectioned view of the electrical arrangement 1 shown in FIGS. 2 and 3 is shown. The insulating body 4 comprises an edge of the power substrate 2, which has a first electrical conductor track 3a on its upper side and a second electrical conductor track 3b on its lower side. A creepage distance 14 is indicated by a circumferential line between the lower electrical conductor track 3b and the upper electrical conductor track 3a. As the first contact region 6 lies completely flat and level on the electrical conductor track 3a, the creepage distance 14 is not reduced by it and a predefined and sufficient electrical insulation between the electrical conductor tracks 3a, 3b is always ensured.

FIG. 5 shows steps of an exemplary embodiment of a method according to the invention for producing an electrical arrangement according to the exemplary embodiments hereinabove. In step 100, an insulating structure is applied to the power substrate. For this purpose, the power substrate is inserted into a mold and its surface is partially overmolded. Only recesses at predefined locations for contacting an electrical conductor track arranged on the power substrate remain blank. In step 200, the conducting structure is produced from a planar sheet of metal. For this purpose, the conducting structure is cut out of sheet metal and then bent (edged), as described above. In step 300, the first contact region is inserted into a recess in the insulating structure 4. In this case, the sharp burrs formed during the punching process are located on an upper side facing away from the power substrate. In this way, they cannot cut into the insulating structure and make the positioning operation difficult/fail. Finally, the first contact region is connected to the electrical conductor track of the power substrate with a material bond, i.e., welded to said substrate. The electrical arrangement can subsequently be cast and/or inserted into a housing. A plug can comprise the connection structure for external electrical contacting.

1. An electrical arrangement (1) comprising:
a power substrate (2) with an electrical conductor track (3),
an insulating structure (4) and
a sheet metal conducting structure (5) having
a first contact region (6),
a connection region (11) and
a first connecting region (9) between the first contact region (6) and the connection region (11), wherein
the contact region (6)
is connected to the electrical conductor track (3) electrically, in a recess (12) in the insulating structure (4),
merges into the connecting region (9) at an angle along an edge (7) running in an X direction and has
a lug (8) for positioning the conducting structure (5), which lug extends in a Y direction over an imaginary extension of the edge (7).

2. The electrical arrangement according to claim 1, wherein the lug (8) is situated in a common plane with the contact region (6).

3. The electrical arrangement according to claim 1, wherein the contact region (6) merges with a finite radius (R) into the connecting region (9).

4. The electrical arrangement according claim 1, wherein the lug (8) comprises a distal region which protrudes in the Y direction at least in sections beyond the connecting region (9).

5. The electrical arrangement according to claim 1, wherein the conducting structure (5) comprises a stamped and/or laser cut metal sheet.

6. The electrical arrangement according to claim 1, wherein the conducting structure (5) further comprises
a second contact region (16) and
a second connecting region between the second contact region (16) and the connection region (11), wherein
the second contact region (16) also extends at an angle along a second edge (17) running in the X direction, which second edge extends in a flush manner with the edge (7) between the first contact region (6) and the first connecting region (9), merging into the second connection region.

7. The electrical arrangement according to claim 1, wherein the first contact region (6) is positioned on the power substrate (2) by the lug (8) in a recess (12) in the insulating structure (4).

8. The electrical arrangement according to claim 1, wherein there is a predefined distance (d) between the first connecting region (9) and the insulating structure (4).

9. The electrical arrangement according to claim 1, wherein an indentation (13) is provided between the lug (8) and the edge (7).

10. A method for producing an electrical arrangement according to claim 1, comprising:
applying (100) an insulating structure (4) onto the power substrate (2),
producing (200) the conducting structure (5) from planar sheet metal,
inserting (300) the first contact region (6) into the recess in the insulating structure (4) and
connecting (400) the first contact region (6) to the electrical conductor track (3) of the power substrate (2) with a material bond.

11. The electrical arrangement according to claim 1, wherein the contact region (6) is connected to the electrical conductor track (3) with a material bond.

12. The electrical arrangement according to claim 7, wherein the first contact region (6) is positioned on the power substrate (2) by the lug (8) in a recess (12) in the insulating structure (4) and is enclosed on multiple sides.

13. The electrical arrangement according to claim 8, wherein the predefined distance (d) is 2 mm or more.
